(19) United States
(12) Patent Application Publication
(10) Pub. No.: US 2018/0287003 A1
(43) Pub. Date: Oct. 4, 2018

(54) SOLAR CELL AND METHOD OF MANUFACTURING SOLAR CELL

(71) Applicant: PANASONIC CORPORATION, Osaka (JP)

(72) Inventors: Minato SENO, Osaka (JP); Shin NANBA, Osaka (JP); Yasufumi TSUNOMURA, Osaka (JP)

(21) Appl. No.: 15/940,454

(22) Filed: Mar. 29, 2018

(30) Foreign Application Priority Data
Mar. 30, 2017 (JP) 2017-069130

(51) Int. Cl. H01L 31/074; H01L 31/0368; H01L 31/0376; H01L 31/0236; H01L 31/18

(52) U.S. Cl. CPC H01L 31/074; H01L 31/03682; H01L 31/1804; H01L 31/02366; H01L 31/03762

(57) ABSTRACT

A solar cell includes: a crystalline semiconductor substrate of a first conductivity type or a second conductivity type; an amorphous layer provided on a principal surface of the substrate; a first-conductivity-type semiconductor layer provided on the amorphous layer; a first high-conduction portion provided inside a first recess portion in the amorphous layer, the first high-conduction portion having a higher conductivity than the amorphous layer, the first high-conduction portion being in contact with the first-conductivity-type semiconductor layer; and a first electrode provided on the first-conductivity-type semiconductor layer. The first-conductivity-type semiconductor layer may be provided in a first region. The solar cell may further include a second-conductivity-type semiconductor layer provided on the amorphous layer in a second region and a second electrode provided on the second-conductivity-type semiconductor layer.

### RELATED APPLICATION

Priority is claimed to Japanese Patent Application No. 2017-069130, filed on Mar. 30, 2017, the entire content of which is incorporated herein by reference.

### BACKGROUND

### 1. Field of the Invention

The present invention relates to solar cells and methods of manufacturing solar cells.

### 2. Description of the Related Art

One of solar cells with high power generation efficiencies is a back-junction solar cell in which an n-type semiconductor layer and a p-type semiconductor layer are both formed in a back surface opposite to a light-receiving surface that receives light. For example, an n-type semiconductor layer and a p-type semiconductor layer are provided on one principal surface of a crystalline semiconductor substrate, and an amorphous semiconductor layer is provided between the semiconductor substrate and the n-type semiconductor layer and p-type semiconductor layer.

An amorphous layer is effective in passivation of a surface of a crystalline substrate but also causes an increase in the series resistance in a solar cell. In order to improve the power generation efficiency, it is preferable that a passivation property and a low resistance property can both be achieved.

The present invention has been made to address this situation and is directed to providing a solar cell with a higher power generation efficiency.

### SUMMARY

A solar cell according to an aspect of the present invention includes: a crystalline semiconductor substrate of a first conductivity type or a second conductivity type; a first amorphous layer provided on a principal surface of the substrate; a first-conductivity-type semiconductor layer provided on the first amorphous layer; a first high-conduction portion provided inside a first recess portion in the first amorphous layer, the first high-conduction portion having a higher conductivity than the first amorphous layer, the first high-conduction portion being in contact with the first-conductivity-type semiconductor layer; and a first electrode provided on the first-conductivity-type semiconductor layer.

Another aspect of the present invention provides a method of manufacturing a solar cell. This method includes: forming an amorphous layer on a principal surface of a crystalline semiconductor substrate of a first conductivity type; forming a first high-conduction portion in the amorphous layer in a first region, the first high-conduction portion having a higher conductivity than the amorphous layer; forming a first-conductivity-type semiconductor layer on the amorphous layer in the first region; forming a second-conductivity-type semiconductor layer on the amorphous layer in a second region different from the first region; and forming a first electrode on the first-conductivity-type semiconductor layer and a second electrode on the second-conductivity-type semiconductor layer.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a plan view illustrating a structure of a solar cell according to an embodiment;

FIG. 2 is a sectional view illustrating a structure of the solar cell illustrated in FIG. 1;

FIG. 3 is a sectional view illustrating a configuration of a first high-conduction portion;

FIGS. 4A to 4C are top views illustrating configurations of first high-conduction portions;

FIG. 5 schematically illustrates a process of manufacturing a solar cell;

FIG. 6 schematically illustrates a process of manufacturing a solar cell;

FIG. 7 schematically illustrates a process of manufacturing a solar cell;

FIGS. 8A to 8C schematically illustrate a process of manufacturing a solar cell;

FIG. 9 schematically illustrates a process of manufacturing a solar cell;

FIG. 10 schematically illustrates a process of manufacturing a solar cell;

FIG. 11 is a sectional view illustrating a structure of a solar cell according to a modification;

FIG. 12 is a sectional view illustrating a structure of a solar cell according to a modification;

FIG. 13 is a sectional view illustrating a structure of a solar cell according to a modification;

FIG. 14 schematically illustrates a process of manufacturing a solar cell according to a modification;

FIG. 15 is a sectional view illustrating a structure of a solar cell according to a modification;

FIG. 16 is a sectional view illustrating a structure of a solar cell according to a modification;

FIG. 17 is a sectional view illustrating a structure of a solar cell according to another embodiment;

FIG. 18 schematically illustrates a process of manufacturing a solar cell;

FIG. 19 schematically illustrates a process of manufacturing a solar cell; and

FIG. 20 schematically illustrates a process of manufacturing a solar cell.

### DETAILED DESCRIPTION

The invention will now be described by reference to the preferred embodiments. This does not intend to limit the scope of the present invention, but to exemplify the invention.

Prior to describing the present invention in concrete terms, an overview will be given. The present embodiment provides a solar cell. The solar cell includes: a crystalline semiconductor substrate of a first conductivity type or a second conductivity type; a first amorphous layer provided on a principal surface of the substrate; a first-conductivity-type semiconductor layer provided on the first amorphous layer; a first high-conduction portion provided inside a first recess portion in the first amorphous layer, the high-conduction portion having a higher conductivity than the first amorphous layer, the high-conduction portion being in contact with the first-conductivity-type semiconductor layer; and a first electrode provided on the first-conductivity-type semiconductor layer. According to the present embodiment, a portion with a high conductivity is provided inside the first recess portion in the first amorphous layer. Thus, a decrease in the passivation property of the amorphous layer can be prevented, and the resistance between the substrate and the first-conductivity-type semiconductor layer can be reduced. Accordingly, the power generation efficiency of the solar cell can be increased.

Hereinafter, embodiments for implementing the present invention will be descried in detail with reference to the drawings. In the descriptions of the drawings, identical elements are given identical reference characters, and duplicate descriptions thereof will be omitted as appropriate.

### First Embodiment

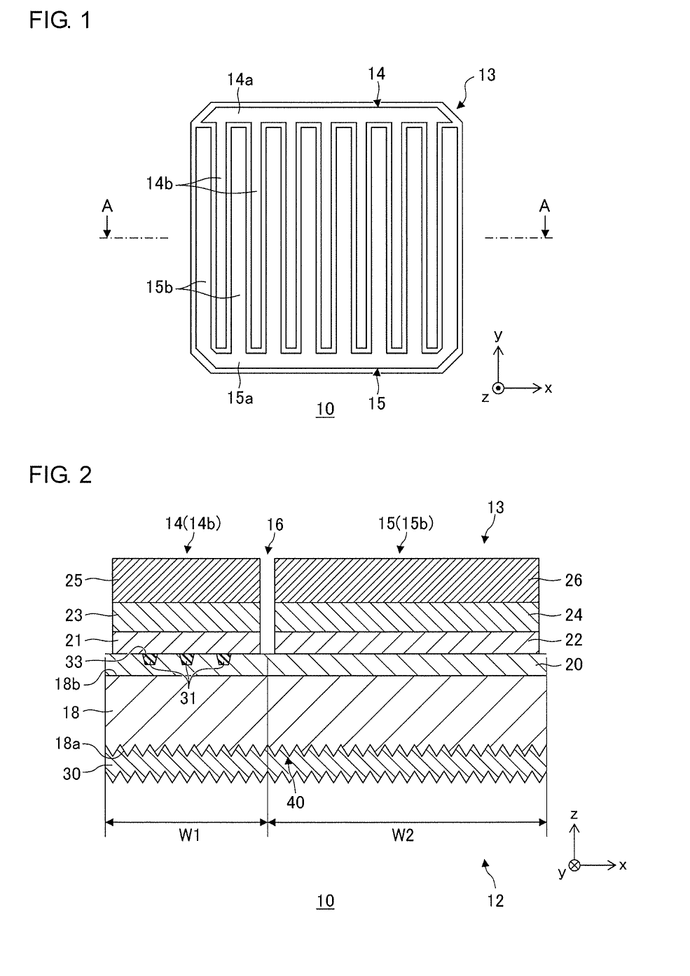

FIG. 1 is a plan view illustrating a solar cell 10 according to an embodiment and illustrates a structure of a back surface 13 of the solar cell 10. The solar cell 10 includes a first electrode 14 and a second electrode 15 that are provided in the back surface 13. The solar cell 10 is a so-called back-contact solar cell. No electrode is provided in a light-receiving surface, and the first electrode 14 and the second electrode 15 having different polarities are both provided in the back surface 13 opposite to the light-receiving surface.

The first electrode 14 includes a first busbar electrode 14a extending in the x-direction and a plurality of first finger electrodes 14b extending in the y-direction intersecting the first busbar electrode 14a. The first electrode 14 is formed into a comb-like shape. The second electrode 15 includes a second busbar electrode 15a extending in the x-direction and a plurality of second finger electrodes 15b extending in the y-direction intersecting the second busbar electrode 15a. The second electrode 15 is formed into a comb-like shape. The first electrode 14 and the second electrode 15 are disposed to interdigitate into each other with their respective comb teeth meshing together. The first electrode 14 and the second electrode 15 may each be an electrode with no busbar that is constituted by a plurality of fingers alone and does not include a busbar.

FIG. 2 is a sectional view illustrating a structure of the solar cell 10 according to the embodiment, taken along the A-A line indicated in FIG. 1. The solar cell 10 includes a substrate 18, an amorphous layer 20, a first-conductivity-type semiconductor layer 21, a second-conductivity-type semiconductor layer 22, a first transparent electrode layer 23, a second transparent electrode layer 24, a first metal electrode layer 25, a second metal electrode layer 26, and a light-receiving surface protection layer 30. The solar cell 10 is a back-junction solar cell having a heterojunction formed in the back surface 13.

The solar cell 10 includes a light-receiving surface 12 and the back surface 13. The light-receiving surface 12 corresponds to the principal surface of the solar cell 10 that primarily receives light (sunlight). Specifically, the light-receiving surface 12 corresponds to the surface that receives most of the light incident on the solar cell 10. Meanwhile, the back surface 13 corresponds to the other principal surface opposite to the light-receiving surface 12.

The substrate 18 is formed of a crystalline semiconductor having a first conductivity type or a second conductivity type. Specific examples of the crystalline semiconductor substrate include a crystalline silicon (Si) wafer, such as a monocrystalline silicon wafer or a polycrystalline silicon wafer, for example. The present embodiment illustrates a case in which the substrate 18 is an n-type monocrystalline silicon wafer having the first conductivity type. The first conductivity type is n-type, and the second conductivity type is p-type. The substrate 18 includes an impurity of the first conductivity type and includes, for example, phosphorus (P) as an n-type impurity with which silicon is doped. The concentration of the n-type impurity in the substrate 18 is not particularly limited and, for example, is approximately 1×10¹⁴/cm³ to 5×10¹⁶/cm³.

The solar cell can also be constituted by a semiconductor substrate other than a crystalline silicon wafer serving as the semiconductor substrate. For example, a compound semiconductor wafer made of gallium arsenide (GaAs) or indium phosphide (InP) may be used. In addition, the semiconductor substrate may have the second conductivity type. The first conductivity type may be p-type, and the second conductivity type may be n-type.

The substrate 18 includes a first principal surface 18a on the side toward the light-receiving surface 12 and a second principal surface 18b on the side toward the back surface 13. The substrate 18 absorbs light incident on the first principal surface 18a and generates an electron and a hole as carriers. A texture structure 40 is provided in the first principal surface 18a to increase the absorption efficiency of the incident light. Meanwhile, such a texture structure similar to the one in the first principal surface 18a need not be provided in the second principal surface 18b, and the second principal surface 18b may be more planar than the first principal surface 18a.

The amorphous layer 20 is provided on the second principal surface 18b of the substrate 18. The amorphous layer 20 is a substantially intrinsic amorphous semiconductor and is formed, for example, by i-type amorphous silicon containing hydrogen. The amorphous layer 20 may be an amorphous insulator layer formed of an amorphous insulator and may be formed, for example, of a silicon compound containing at least one of oxygen (O) and nitrogen (N) or an aluminum compound containing at least one of oxygen and nitrogen.

The amorphous layer 20 has a thickness of, for example, approximately 1 nm to 200 nm and preferably has a thickness of 2 nm to 25 nm. The amorphous layer 20 may be formed to have a uniform thickness on the second principal surface 18b or may have a thickness that partially varies. For example, the amorphous layer 20 may be relatively thicker at a portion where a first recess portion 33, described later, is provided and may be relatively thinner at a portion where the first recess portion 33 is not provided. For example, the amorphous layer 20 may be thicker in a first region W1 and thinner in a second region W2.

In the present specification, a substantially intrinsic semiconductor is also referred to as an “i-type semiconductor.” The substantially intrinsic semiconductor includes a semiconductor layer deposited without actively using an element that results in an n-type or p-type impurity and includes a semiconductor layer formed without supplying a dopant gas during formation through chemical vapor deposition (CVD) or the like. Specifically, the substantially intrinsic semiconductor includes silicon obtained by supplying silane (SiH₄) or the like diluted with hydrogen (H₂) without supplying a dopant gas, such as diborane (B₂H₆) or phosphine (PH₃).

The first-conductivity-type semiconductor layer 21 and the second-conductivity-type semiconductor layer 22 are provided on the amorphous layer 20. The first-conductivity-type semiconductor layer 21 is provided on the amorphous layer 20 in the first region W1, and the second-conductivity-type semiconductor layer 22 is provided on the amorphous layer 20 in the second region W2 different from the first region W1. The first-conductivity-type semiconductor layer 21 and the second-conductivity-type semiconductor layer 22 are formed into a comb-like shape to correspond to the first electrode 14 and the second electrode 15, respectively, and interdigitate into each other. Thus, the first region W1 and the second region W2 are arrayed in an alternating manner in the x-direction.

The first region W1 is a first-conductivity-type side and collects, among the carriers generated in the substrate 18, carriers in the first-conductivity-type side. Since the substrate 18 is of the first conductivity type, the first region W1 can be regarded as a region where majority carriers are collected. Meanwhile, the second region W2 is a second-conductivity-type side and collects carriers in the second-conductivity-type side, namely, minority carriers. When the first conductivity type is n-type and the second conductivity type is p-type, the first region W1 collects electrons, and the second region W2 collects holes.

The minority carriers have a lower collection efficiency than the majority carriers. Therefore, in order to increase the power generation efficiency in the cell as a whole, the second region W2, or the minority carrier side, has a second area S2 that is greater than a first area S1 of the first region W1, or the majority carrier side. The ratio S2/S1 of the second area S2 to the first area S1 may be set to no lower than 1.1 nor higher than 5 and may, for example, be set to no lower than 2 nor higher than 4.

Similarly to the substrate 18, the first-conductivity-type semiconductor layer 21 is a semiconductor layer containing an impurity of the first conductivity type and is, for example, a silicon layer containing phosphorus (P). The first-conductivity-type semiconductor layer 21 preferably has a higher impurity concentration than the substrate 18. The impurity concentration in the first-conductivity-type semiconductor layer 21 is no lower than 1×10¹⁸/cm³ and is preferably no lower than 1×10²⁰/cm³. The first-conductivity-type semiconductor layer 21 has a thickness of, for example, approximately 2 nm to 50 nm.

The first-conductivity-type semiconductor layer 21 is formed of an amorphous or crystalline semiconductor. When the first-conductivity-type semiconductor layer 21 is formed of an amorphous semiconductor, the first-conductivity-type semiconductor layer 21 is formed, for example, of n-type amorphous silicon containing hydrogen. When the first-conductivity-type semiconductor layer 21 is formed of a crystalline semiconductor, the first-conductivity-type semiconductor layer 21 includes at least one of n-type monocrystalline silicon, polycrystalline silicon, and crystallite silicon, for example. The first-conductivity-type semiconductor layer 21 may include both an amorphous portion and a crystalline portion.

The second-conductivity-type semiconductor layer 22 is a semiconductor layer containing an impurity of the second conductivity type different from the first conductivity type and is, for example, a silicon layer containing boron (B). The second-conductivity-type semiconductor layer 22 has a thickness of, for example, approximately 2 nm to 50 nm. The second-conductivity-type semiconductor layer 22 is formed of an amorphous or crystalline semiconductor and includes p-type amorphous silicon containing hydrogen or at least one of p-type monocrystalline silicon, polycrystalline silicon, and crystallite silicon. The second-conductivity-type semiconductor layer 22 may include both an amorphous portion and a crystalline portion.

The first transparent electrode layer 23 is provided on the first-conductivity-type semiconductor layer 21, and the second transparent electrode layer 24 is provided on the second-conductivity-type semiconductor layer 22. The first transparent electrode layer 23 and the second transparent electrode layer 24 are formed, for example, of a transparent conductive oxide (TCO) obtained by doping tin oxide (SnO₂), zinc oxide (ZnO), indium tin oxide (ITO), or the like with tin (Sn), antimony (Sb), fluorine (F), aluminum (Al), or the like. In the present embodiment, the first transparent electrode layer 23 and the second transparent electrode layer 24 are formed of indium tin oxide. The first transparent electrode layer 23 and the second transparent electrode layer 24 can each have a thickness of approximately 50 nm to 100 nm, for example.

The first metal electrode layer 25 is provided on the first transparent electrode layer 23, and the second metal electrode layer 26 is provided on the second transparent electrode layer 24. The first metal electrode layer 25 and the second metal electrode layer 26 are conductive material layers containing metal such as copper (Cu), tin (Sn), gold (Au), silver (Ag), nickel (Ni), or titanium (Ti). The first metal electrode layer 25 and the second metal electrode layer 26 may each be constituted by a single layer or by a plurality of layers. The first metal electrode layer 25 and the second metal electrode layer 26 each include, for example, a seed layer of approximately 50 nm to 1100 nm, a first plated layer of approximately 11 μm to 50 μm, and a second plated layer of approximately 1 μm to 5 μm. For example, the seed layer and the first plated layer are formed of copper (Cu), and the second plated layer is formed of tin (Sn).

In the present embodiment, the first electrode 14 is constituted by the first transparent electrode layer 23 and the first metal electrode layer 25, and the second electrode 15 is constituted by the second transparent electrode layer 24 and the second metal electrode layer 26. The first electrode 14 collects carriers in the first-conductivity-type side, and the second electrode 15 collects carriers in the second-conductivity-type side. An isolation groove 16 is provided between the first electrode 14 and the second electrode 15, and the first electrode 14 and the second electrode 15 are thus electrically isolated from each other. An insulating material may be provided inside the isolation groove 16. For example, an insulating material such as silicon oxide (SiO), silicon nitride (SiN), or silicon oxynitride (SiON) may be provided inside the isolation groove 16.

The light-receiving surface protection layer 30 is provided on the first principal surface 18a. The light-receiving surface protection layer 30 functions as a passivation layer for the first principal surface 18a. This passivation layer may include at least one of a substantially intrinsic amorphous semiconductor layer, an amorphous semiconductor layer of the first conductivity type, and an amorphous semiconductor layer or an insulation layer of the second conductivity type. The passivation layer can be formed of amorphous silicon containing hydrogen, silicon oxide, silicon nitride, silicon oxynitride, or the like. The passivation layer has a thickness of, for example, approximately 2 nm to 100 nm.

The light-receiving surface protection layer 30 may further have a function of an antireflection film or a protection film. An antireflection film or a protection film can be formed of silicon oxide, silicon nitride, silicon oxynitride, or the like. The thickness of the antireflection film or the protection film is set as appropriate in accordance with the antireflection characteristics, for example, and is approximately 50 nm to 1100 nm, for example.

The solar cell 10 further includes a first high-conduction portion 31. The first high-conduction portion 31 is formed inside the first recess portion 33 in the amorphous layer 20 in the first region W1 and is in contact with the first-conductivity-type semiconductor layer 21. The first high-conduction portion 31 is a portion having a higher conductivity than the amorphous layer 20. The first high-conduction portion 31 is formed of a semiconductor material having a higher conductivity than the amorphous layer 20. The first high-conduction portion 31 may have the first conductivity type. The first high-conduction portion 31 is formed, for example, of an i-type or n-type crystalline semiconductor and includes at least one of i-type or n-type monocrystalline silicon, polycrystalline silicon, and crystallite silicon. The first high-conduction portion 31 may be formed of an n-type amorphous semiconductor and may include, for example, n-type amorphous silicon containing hydrogen.

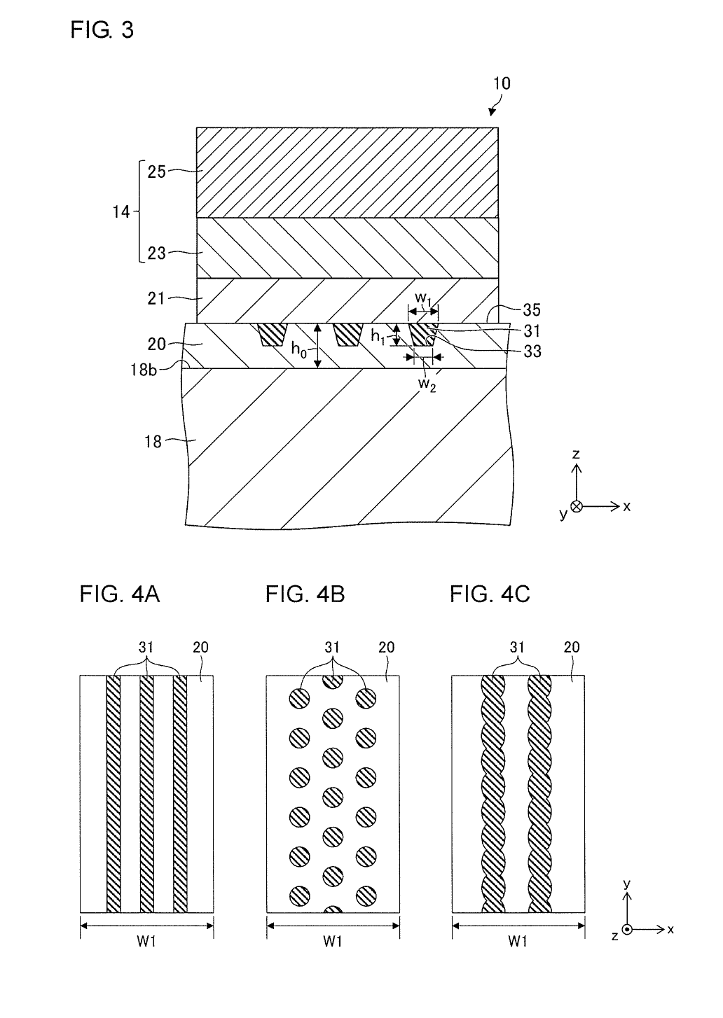

FIG. 3 is a sectional view illustrating a configuration of the first high-conduction portion 31 and corresponds to an enlarged view of the vicinity of the first high-conduction portion 31 illustrated in FIG. 2. The first recess portion 33 is recessed toward the second principal surface 18b from an interface 35 between the amorphous layer 20 and the first-conductivity-type semiconductor layer 21. The first recess portion 33 has a depth or height h₁ smaller than the thickness h₀ of the amorphous layer 20, that is, smaller than the height h₀ from the second principal surface 18b of the substrate 18 to the interface 35 between the amorphous layer 20 and the first-conductivity-type semiconductor layer 21. Therefore, the first recess portion 33 does not penetrate through the amorphous layer 20. The first high-conduction portion 31 in the first recess portion 33 is spaced apart from the second principal surface 18b of the substrate 18. The depth h₁ of the first recess portion 33 is, for example, approximately 5% to 95% of the height h₀ from the second principal surface 18b to the interface 35.

The first recess portion 33 has a section along a plane orthogonal to the depthwise direction, and the size of the section decreases as the distance from the interface 35 between the amorphous layer 20 and the first-conductivity-type semiconductor layer 21 increases. As illustrated in FIG. 3, the width w₁ of the first recess portion 33 at the interface 35 is preferably greater than the width w₂ of the first recess portion 33 at the bottom. The shape of the section of the first recess portion 33 along a plane orthogonal to the depthwise direction is not particularly limited and is, for example, circular, elliptical, or polygonal, such as rectangular. Therefore, the first recess portion 33 has a shape approximated, for example, to a truncated cone or a prismoid. The first high-conduction portion 31 provided inside the first recess portion 33 has a similar shape.

A plurality of first recess portions 33 are provided in the first region W1. The plurality of first recess portions 33 are provided to occupy a predetermined area of the interface 35 in the first region W1, and a plurality of first high-conduction portions 31 are provided to occupy a predetermined volume in the amorphous layer 20 in the first region W1. The plurality of first high-conduction portions 31 are provided, for example, to occupy no less than 0.5% nor more than 20% of the volume of the amorphous layer 20 and are preferably provided to occupy no less than 1% nor more than 10% of the volume of the amorphous layer 20. When observed along a section intersecting the second principal surface 18b as illustrated in FIG. 2 or 3, the plurality of first high-conduction portions 31 preferably occupy no less than 0.5% nor more than 20% of the area of the amorphous layer 20 and more preferably occupy no less than 1% nor more than 10% of the area of the amorphous layer 20. With such numerical ranges, a decrease in the passivation property of the amorphous layer 20 can be prevented, and a resistance reduction effect of the first high-conduction portions 31 can be achieved favorably.

FIGS. 4A to 4C are top views illustrating configurations of the first high-conduction portions 31 and correspond to diagrams illustrating the first high-conduction portions 31 and the amorphous layer 20 as viewed from the above. For example, as illustrated in FIG. 4A, the first high-conduction portions 31 are each provided in a line shape extending in the y-direction. The first high-conduction portions 31 may be provided in a spot pattern with a gap provided therebetween in the y-direction, as illustrated in FIG. 4B. As illustrated in FIG. 4C, adjacent spots may be connected together to form a line shape with a varied width in the x-direction. Aside from the above, line-shaped and spot-patterned first high-conduction portions 31 as illustrated in FIGS. 4A to 4C may be mixedly provided.

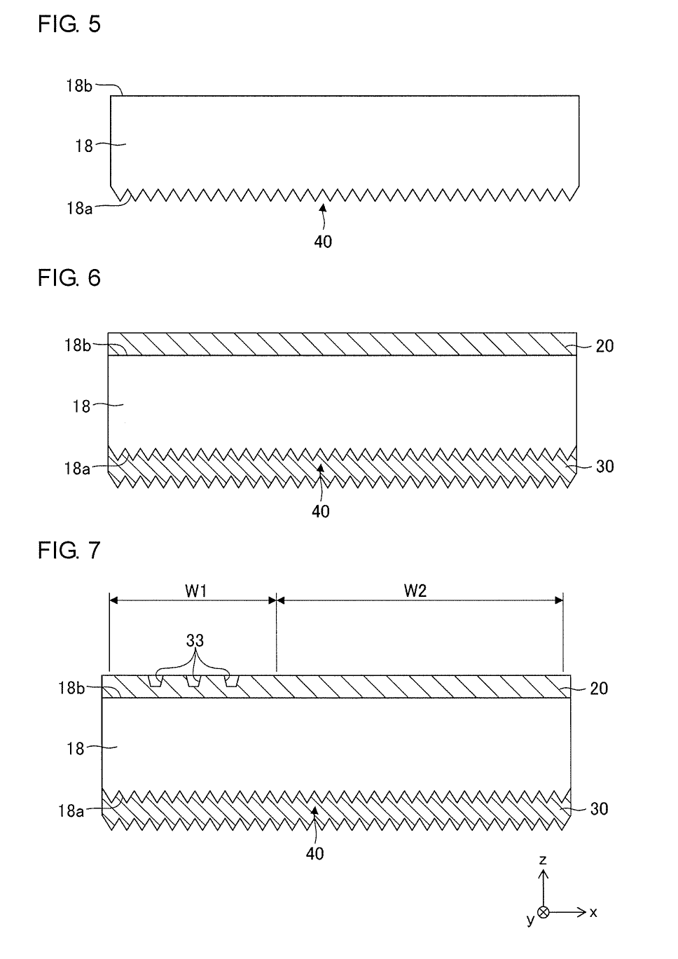

Next, a method of manufacturing the solar cell 10 will be described. First, as illustrated in FIG. 5, the texture structure 40 is provided in the first principal surface 18a, and the substrate 18 is prepared in which the second principal surface 18b is more planar than the first principal surface 18a.

Next, as illustrated in FIG. 6, the light-receiving surface protection layer 30 is formed on the first principal surface 18a, and the amorphous layer 20 is formed on the second principal surface 18b. The amorphous layer 20 and the light-receiving surface protection layer 30 can be formed through a chemical vapor deposition (CVD) method, such as a plasma CVD method. For example, when the amorphous layer 20 and the light-receiving surface protection layer 30 are amorphous silicon layers, the amorphous layer 20 and the light-receiving surface protection layer 30 may be formed simultaneously. The light-receiving surface protection layer 30 need not be formed simultaneously with the amorphous layer 20 and may be formed before the amorphous layer 20 is formed or after the amorphous layer 20 is formed.

Then, as illustrated in FIG. 7, the first recess portions 33 are formed in a portion of the amorphous layer 20. The first recess portions 33 are provided in a portion that is in the first region W1 while avoiding a portion that is in the second region W2. The first recess portions 33 can be formed by subjecting a portion of the amorphous layer 20 to wet etching or dry etching. For example, the portion of the amorphous layer 20 that corresponds to the first recess portions 33 may be selectively removed by forming a patterning mask on the amorphous layer 20. The first recess portions 33 may be formed by irradiating a portion of the amorphous layer 20 with a laser to cause ablation.

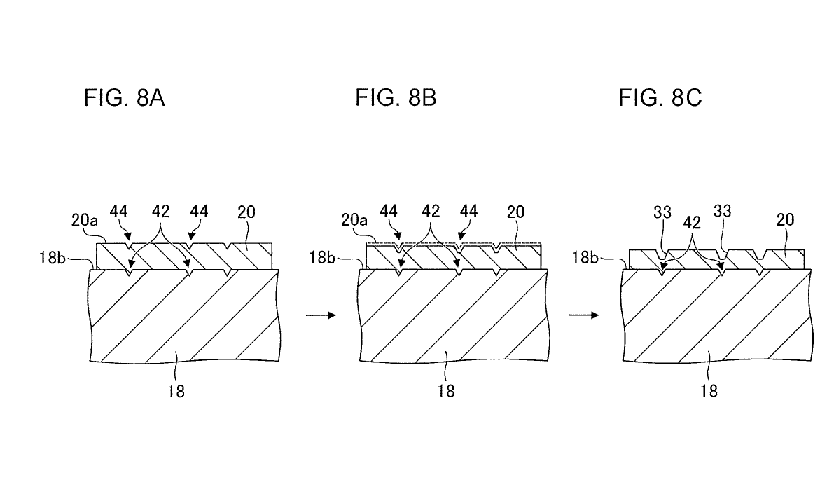

FIGS. 8A to 8C are sectional views schematically illustrating an example of a method of forming the first recess portions 33. In the method illustrated in FIGS. 8A to 8C, the first recess portions 33 are formed in the amorphous layer 20 with the use of fine recess portions 42 present in the second principal surface 18b of the substrate 18. The second principal surface 18b of the substrate 18 is, in a strict sense, not planar at an atomic level and typically has fine concavities and convexities. The sizes of the fine recess portions 42 in the second principal surface 18b are smaller than any recess portion in the texture structure 40 in the first principal surface 18a and are approximately 1 nm to 100 nm. When the amorphous layer 20 is formed on such a second principal surface 18b, fine recess portions 44, reflecting the fine recess portions 42 in the second principal surface 18b, appear in an upper surface 20a of the amorphous layer 20, as illustrated in FIG. 8A. In other words, the fine recess portions 44 appear in the amorphous layer 20 at positions corresponding to the fine recess portions 42 in the second principal surface 18b.

When the upper surface 20a of the amorphous layer 20 in which the fine recess portions 44 described above are present is subjected to isotropic etching, the upper surface 20a is etched such that the sizes of the fine recess portions 44 gradually increase, as illustrated in FIG. 8B. As the etching process progresses further from the state illustrated in FIG. 8B, the amorphous layer 20 having the first recess portions 33 can be formed, as illustrated in FIG. 8C. When the amorphous layer 20 is an amorphous silicon layer, wet etching with the use of a hydrofluoric acid (HF) aqueous solution, an alkaline solution, or the like can be employed. Aside from the above, dry etching, such as plasma etching, may be employed.

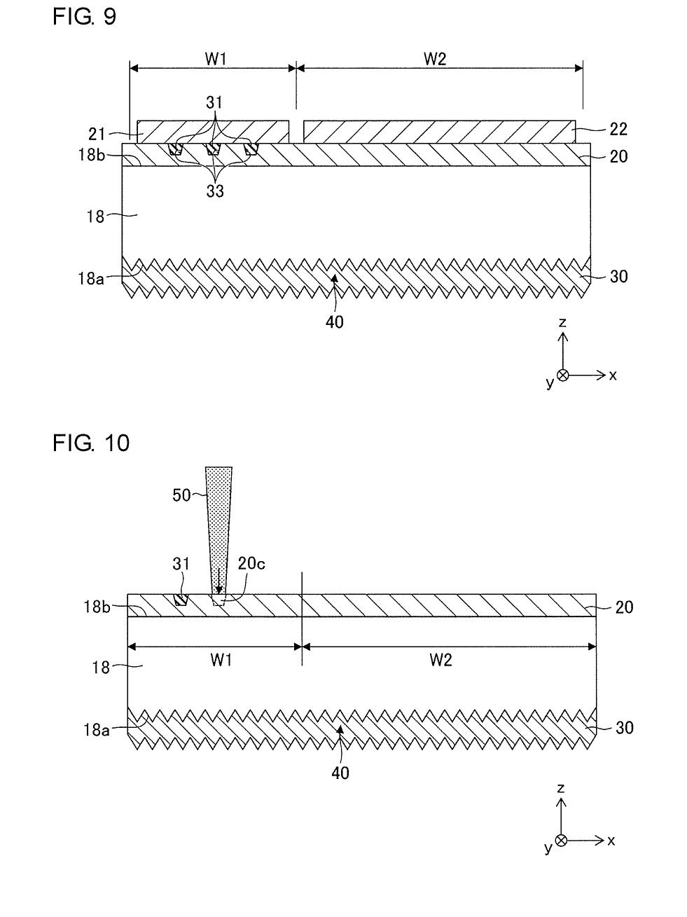

Next, as illustrated in FIG. 9, the first high-conduction portions 31 are formed in the respective first recess portions 33 in the amorphous layer 20, and the first-conductivity-type semiconductor layer 21 is formed on the amorphous layer 20 in the first region W1. In addition, the second-conductivity-type semiconductor layer 22 is formed on the amorphous layer 20 in the second region W2. The first high-conduction portions 31, the first-conductivity-type semiconductor layer 21, and the second-conductivity-type semiconductor layer 22 can be formed through a chemical vapor deposition (CVD) method, such as a plasma CVD method. When the first high-conduction portions 31 are formed of a semiconductor of the first conductivity type, the first high-conduction portions 31 and the first-conductivity-type semiconductor layer 21 may be formed continuously.

The first high-conduction portions 31 can be formed through another method. FIG. 10 is a sectional view schematically illustrating an example of a method of forming the first high-conduction portion 31 and illustrates a method in which the first high-conduction portion 31 is formed without forming the first recess portion 33. In the method illustrated in FIG. 10, the amorphous layer 20 is irradiated with a laser 50 to heat a portion of the amorphous layer 20, and thus the conductivity of an irradiation region 20c irradiated with the laser 50 is increased from the conductivity held before the laser irradiation. Specifically, by appropriately setting the irradiation conditions such as the energy and the pulse duration of the laser 50, the irradiation region 20c can be locally heated, and the irradiation region 20c alone can be transformed from being amorphous to being crystalline. Thus, the first high-conduction portion 31 having a higher conductivity than the amorphous layer 20 that has not been irradiated with the laser can be formed.

When the first high-conduction portions 31 are formed through the method illustrated in FIG. 10, the first-conductivity-type semiconductor layer 21 is formed on the amorphous layer 20 in the first region W1 after the first high-conduction portions 31 are formed. In addition, the second-conductivity-type semiconductor layer 22 is formed on the amorphous layer 20 in the second region W2.

Subsequently, the first transparent electrode layer 23 and the first metal electrode layer 25 are formed on the first-conductivity-type semiconductor layer 21, and the second transparent electrode layer 24 and the second metal electrode layer 26 are formed on the second-conductivity-type semiconductor layer 22. The first transparent electrode layer 23 and the second transparent electrode layer 24 are formed through a CVD method such as a plasma CVD method or through a thin-film deposition method such as a sputtering method. The first metal electrode layer 25 and the second metal electrode layer 26 are formed through a sputtering method, a plating method, or the like.

Thus, the solar cell 10 illustrated in FIG. 2 is fabricated. In the manufacturing method described above, the second-conductivity-type semiconductor layer 22 is formed after the first recess portions 33 are formed in the amorphous layer 20 in the first region W1. Alternatively, the second-conductivity-type semiconductor layer 22 may be formed before the first recess portions 33 are formed. In this case, the second-conductivity-type semiconductor layer 22 is formed on the amorphous layer 20 in the second region W2. Then, the first recess portions 33 are formed in the amorphous layer 20 in the first region W1, and the first high-conduction portions 31 and the first-conductivity-type semiconductor layer 21 are formed.

According to the present embodiment, the first high-conduction portions 31 are provided inside the first recess portions 33 in the amorphous layer 20 in the first region W1. Thus, the series resistance in the first region W1 can be reduced as compared to the case in which the first high-conduction portions 31 are not provided. In addition, the first recess portions 33 do not penetrate through the amorphous layer 20 and are spaced apart from the second principal surface 18b of the substrate 18. Thus, the entire surface of the second principal surface 18b can be passivated by the amorphous layer 20. Therefore, according to the present embodiment, a decrease in the passivation property of the amorphous layer 20 can be prevented, and the series resistance in the first region W1 can be reduced. Thus, the power generation efficiency of the solar cell 10 can be improved.

An aspect of the present embodiment is as follows. A solar cell (10) according to an aspect includes:

a crystalline semiconductor substrate (18) of a first conductivity type or a second conductivity type;

a first amorphous layer (amorphous layer 20) provided on a principal surface (second principal surface 18b) of the substrate (18);

a first-conductivity-type semiconductor layer (21) provided on the first amorphous layer (amorphous layer 20);

a first high-conduction portion (31) provided inside a first recess portion (33) in the first amorphous layer (amorphous layer 20), the first high-conduction portion (31) having a higher conductivity than the first amorphous layer (amorphous layer 20), the first high-conduction portion (31) being in contact with the first-conductivity-type semiconductor layer (21); and

a first electrode (14) provided on the first-conductivity-type semiconductor layer (21).

The first amorphous layer and the first-conductivity-type semiconductor layer (21) may be provided on the principal surface (second principal surface 18b) of the substrate (18) in a first region (W1), and the solar cell (10) may further include

a second amorphous layer provided on the principal surface (second principal surface 18b) of the substrate (18) in a second region (W2) different from the first region (W1),

a second-conductivity-type semiconductor layer (22) provided on the second amorphous layer, and

a second electrode (15) provided on the second-conductivity-type semiconductor layer (22).

The substrate (18) may be of the first conductivity type, and an area of the first region (W1) may be smaller than an area of the second region (W2).

The first amorphous layer and the second amorphous layer may be constituted by a shared amorphous layer (20).

The first high-conduction portion (31) may include an amorphous semiconductor of the first conductivity type.

The first high-conduction portion (31) may include a crystalline semiconductor.

The first-conductivity-type semiconductor layer (21) may include an amorphous semiconductor of the first conductivity type.

The first high-conduction portion (31) and the first-conductivity-type semiconductor layer (21) may be formed of the same material.

The first recess portion (33) may have a depth (h₁) that is no less than 5% nor more than 95% of a height (h₀) from the principal surface (second principal surface 18b) of the substrate (18) to an interface (35) between the amorphous layer (20) and the first-conductivity-type semiconductor layer (21).

The first recess portion (33) may have a section along a plane orthogonal to a depthwise direction, and a size of the section may decrease as a distance from the interface (35) between the amorphous layer (20) and the first-conductivity-type semiconductor layer (21) increases.

The first high-conduction portion (31) may have a volume that is no less than 0.5% nor more than 20% of a volume of the amorphous layer (20) in the first region (W1).

A fine recess portion (42) may be provided in the principal surface (second principal surface 18b) of the substrate (18) at a position corresponding to the first high-conduction portions (31).

Another aspect of the present embodiment provides a method of manufacturing a solar cell (10). This method includes:

forming an amorphous layer (20) on a principal surface of a crystalline semiconductor substrate (18) of a first conductivity type;

forming a first high-conduction portion (31) in the amorphous layer (20) in a first region (W1), the first high-conduction portion (31) having a higher conductivity than the amorphous layer (20);

forming a first-conductivity-type semiconductor layer (21) on the amorphous layer (20) in the first region (W1);

forming a second-conductivity-type semiconductor layer (22) on the amorphous layer (20) in a second region (W2) different from the first region (W1); and

forming a first electrode (14) on the first-conductivity-type semiconductor layer (21) and a second electrode (15) on the second-conductivity-type semiconductor layer (22).

The first high-conduction portion (31) may be formed inside a first recess portion (33) formed in the amorphous layer (20) in the first region (W1).

The first high-conduction portion (31) may be formed by heating a portion of the amorphous layer (20) in the first region (W1).

### (First Modification)

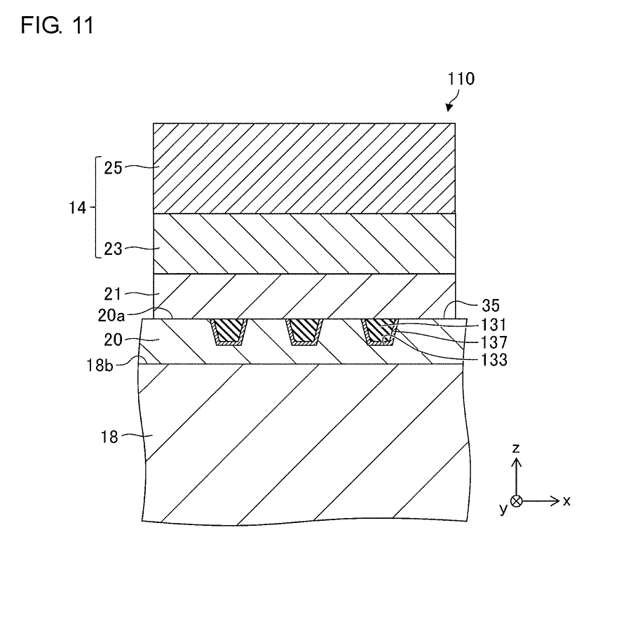

FIG. 11 is a sectional view illustrating a structure of a solar cell 110 according to a modification and illustrates a configuration around a first high-conduction portion 131. The present modification differs from the embodiment described above in that the first high-conduction portion 131 and an oxide layer 137 are provided inside a first recess portion 133 in the amorphous layer 20 in the first region W1.

The oxide layer 137 is provided at an interface between the amorphous layer 20 and the first high-conduction portion 131. The oxide layer 137 is formed of a material containing oxygen (O) and formed, for example, of silicon oxide (SiO), silicon oxynitride (SiON), or the like. The oxide layer 137 may be amorphous silicon containing oxygen. The first high-conduction portion 131 is covered by the oxide layer 137. Thus, a decrease in the passivation property resulting from providing the first high-conduction portion 131 in a portion of the amorphous layer 20 can be suppressed.

The oxide layer 137 may be provided at the interface 35 between the amorphous layer 20 and the first-conductivity-type semiconductor layer 21. Meanwhile, the oxide layer 137 may be provided to avoid an interface between the first high-conduction portion 131 and the first-conductivity-type semiconductor layer 21. Thus, an electrical contact between the first high-conduction portion 131 and the first-conductivity-type semiconductor layer 21 can be made more favorable.

The oxide layer 137 is provided inside the first recess portion 133 through a CVD method or the like after forming the first recess portion 133, similarly to the embodiment described above. After the oxide layer 137 is formed inside the first recess portion 133, the first high-conduction portion 131 is formed on the oxide layer 137. When the oxide layer 137 is formed inside the first recess portion 133, an oxide layer may also be formed simultaneously on the upper surface 20a of the amorphous layer 20. The oxide layer on the upper surface 20a of the amorphous layer 20 may be removed before the first-conductivity-type semiconductor layer 21 is formed. Alternatively, the first-conductivity-type semiconductor layer 21 may be formed on the oxide layer without removing the oxide layer on the upper surface 20a of the amorphous layer 20. In the latter case, the oxide layer 137 may be provided at the interface 35 between the amorphous layer 20 and the first-conductivity-type semiconductor layer 21.

In a solar cell (110) according to an aspect, an oxide layer (137) may be provided at an interface between the amorphous layer (20) and a first high-conduction portion (131).

### (Second Modification)

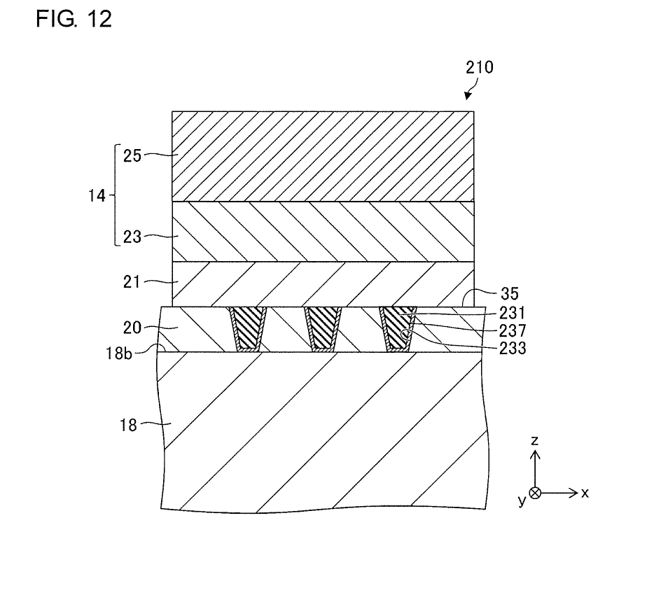

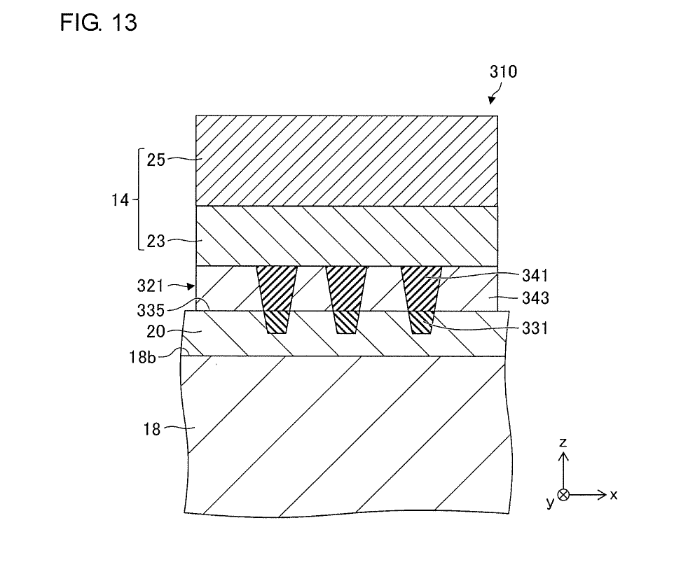

FIG. 12 is a sectional view illustrating a structure of a solar cell 210 according to a modification and illustrates a configuration around a first high-conduction portion 231. The present modification differs from the modification described above in that a first recess portion 233 provided in the amorphous layer 20 in the first region W1 penetrates through the amorphous layer 20 and reaches the substrate 18.

The first recess portion 233 is provided to penetrate through the amorphous layer 20 in the first region W1. Therefore, the bottom of the first recess portion 233 is constituted by an interface between the first recess portion 233 and the substrate 18. The first high-conduction portion 231 and an oxide layer 237 are provided inside the first recess portion 233. The oxide layer 237 is provided at an interface between the amorphous layer 20 and the first high-conduction portion 231 and an interface between the substrate 18 and the first high-conduction portion 231. Therefore, the first high-conduction portion 231 is covered from the substrate 18 and the amorphous layer 20 by the oxide layer 237.

According to the present modification, the first high-conduction portion 231 can be provided in the further proximity of the second principal surface 18b of the substrate 18. Thus, the resistance in the first region W1 can be further reduced. In the meantime, if the first high-conduction portion 231 is in direct contact with the second principal surface 18b of the substrate 18, the passivation property may decrease in that portion. In the present modification, the oxide layer 237 is provided between the substrate 18 and the first high-conduction portion 231. Thus, the surface of the substrate 18 can be passivated favorably even at the portion where the first recess portion 233 penetrates through the amorphous layer 20. Thus, while achieving both the passivation property and the low resistance property, the power generation efficiency of the solar cell 210 can be improved.

In a further modification, the oxide layer 237 need not be provided at an interface between the substrate 18 and the first high-conduction portion 231.

In a solar cell (210) according to an aspect, a first recess portion (233) may penetrate through the amorphous layer (20) to reach the substrate (18).

An oxide layer (237) may be provided at an interface between the substrate (18) and a first high-conduction portion (231).

The oxide layer (237) need not be provided at the interface between the substrate (18) and the first high-conduction portion (231).

### (Third Modification)

FIG. 13 is a sectional view illustrating a structure of a solar cell 310 according to a modification and illustrates a configuration around a first high-conduction portion 331. The present modification differs from the embodiment described above in that a first-conductivity-type semiconductor layer 321 includes a crystalline semiconductor portion 341 and an amorphous semiconductor portion 343 and the crystalline semiconductor portion 341 is provided on the first high-conduction portion 331.

The first-conductivity-type semiconductor layer 321 includes the crystalline semiconductor portion 341 and the amorphous semiconductor portion 343. The crystalline semiconductor portion 341 is formed of a crystalline semiconductor of the first conductivity type and includes at least one of n-type monocrystalline silicon, polycrystalline silicon, and crystallite silicon, for example. The amorphous semiconductor portion 343 is formed of an amorphous semiconductor of the first conductivity type and is formed, for example, of n-type amorphous silicon containing hydrogen.

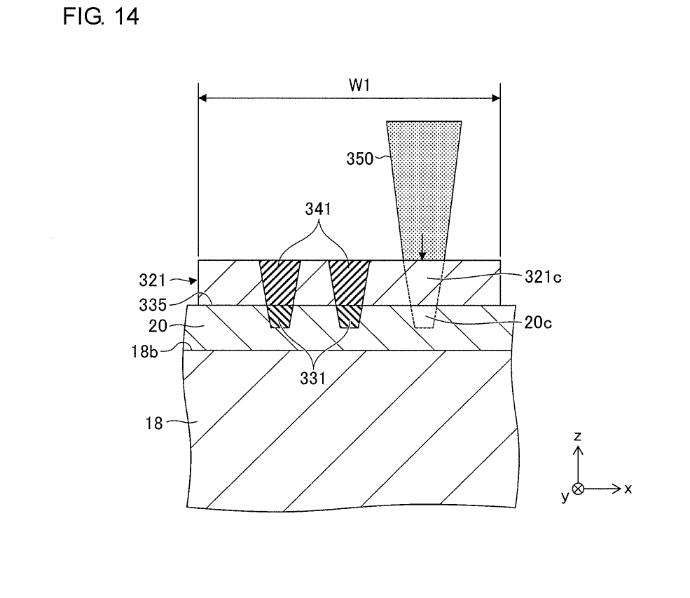

FIG. 14 schematically illustrates a process of manufacturing the solar cell 310 according to the modification and illustrates a method of forming the first high-conduction portion 331 and the crystalline semiconductor portion 341. In the method illustrated in FIG. 14, similarly to the method illustrated in FIG. 10 according to the embodiment described above, the first high-conduction portion 331 and the crystalline semiconductor portion 341 are formed through irradiation with a laser 350.

First, the amorphous layer 20 is formed on the second principal surface 18b, and the first-conductivity-type semiconductor layer 321 is formed on the amorphous layer 20 in the first region W1. The first-conductivity-type semiconductor layer 321 is formed of an amorphous semiconductor of the first conductivity type. Then, the first-conductivity-type semiconductor layer 321 is irradiated with the laser 350 from the above, and thus a portion of the first-conductivity-type semiconductor layer 321 and a portion of the amorphous layer 20 are heated. An irradiation region 321c in the first-conductivity-type semiconductor layer 321 is transformed into the crystalline semiconductor portion 341 upon being heated by the laser 350. In a similar manner, the irradiation region 20c in the amorphous layer 20 is transformed into the first high-conduction portion 331 upon being heated by the laser 350. The first high-conduction portion 331 and the crystalline semiconductor portion 341 are formed through the shared laser irradiation. Thus, the crystalline semiconductor portion 341 is formed immediately above the first high-conduction portion 331.

According to the present modification, the crystalline semiconductor portion 341 of the first conductivity type is formed on the first high-conduction portion 331. Thus, the resistance in the first region W1 can be further reduced. Accordingly, the power generation efficiency of the solar cell 310 can be further improved.

In the illustrated example, the crystalline semiconductor portion 341 in the first-conductivity-type semiconductor layer 321 is formed to reach an interface 335 between the amorphous layer 20 and the first-conductivity-type semiconductor layer 321 and to be in contact with the first high-conduction portion 331. The crystalline semiconductor portion 341 may be provided not to reach the interface 335 between the amorphous layer 20 and the first-conductivity-type semiconductor layer 321 and may be provided to be spaced apart from the interface 335. In other words, the crystalline semiconductor portion 341 may have a height that is smaller than the thickness of the first-conductivity-type semiconductor layer 321.

The first high-conduction portion 331 may not be formed in the amorphous layer 20. For example, there is a case in which the amorphous layer 20 is not irradiated with a laser having sufficient energy and a portion of the amorphous layer 20 is not reformed. Even in such a case, forming the crystalline semiconductor portion 341 of the first conductivity type makes it possible to reduce the contact resistance between the first-conductivity-type semiconductor layer 321 and the first electrode 14.

In a solar cell (310) according to an aspect, a first-conductivity-type semiconductor layer (321) may include an amorphous semiconductor portion (343) of the first conductivity type provided on the amorphous layer (20) and a crystalline semiconductor portion (341) of the first conductivity type provided on a first high-conduction portion (331).

### (Fourth Modification)

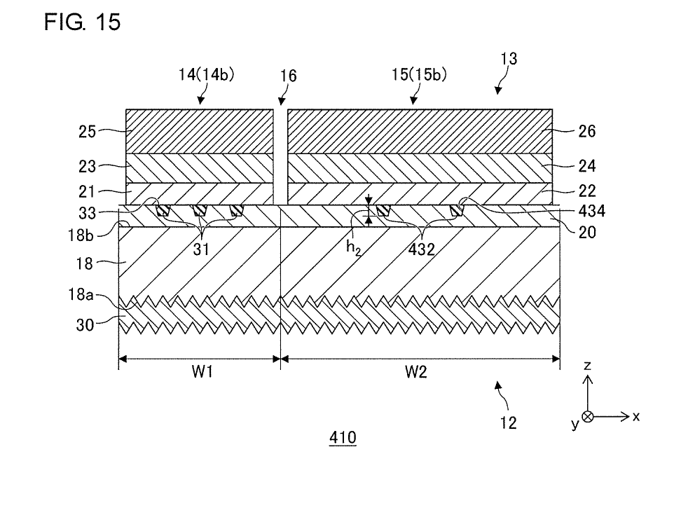

FIG. 15 is a sectional view illustrating a structure of a solar cell 410 according to a modification. The present modification differs from the embodiment described above in that a second recess portion 434 is provided in the amorphous layer 20 in the second region W2 and a second high-conduction portion 432 is provided inside the second recess portion 434.

Similarly to the first high-conduction portion 31, the second high-conduction portion 432 is a portion having a higher conductivity than the amorphous layer 20. The second high-conduction portion 432 is formed of a semiconductor material having a higher conductivity than the amorphous layer 20 and is formed, for example, of an i-type or p-type crystalline semiconductor. The second high-conduction portion 432 includes at least one of i-type or p-type monocrystalline silicon, polycrystalline silicon, and crystallite silicon. The second high-conduction portion 432 may be formed of a p-type amorphous semiconductor and may include, for example, p-type amorphous silicon containing hydrogen.

The amount of the second high-conduction portion 432 provided per unit area is smaller than the amount of the first high-conduction portions 31 provided per unit area. For example, the volume of the second high-conduction portion 432 provided per unit area in the second region W2 is smaller than the volume of the first high-conduction portion 31 provided per unit area in the first region W1. The volume of the second high-conduction portion 432 can be adjusted by varying the height h₂ of the second high-conduction portion 432, the area occupied by the second high-conduction portion 432 at an interface between the amorphous layer 20 and the second-conductivity-type semiconductor layer 22, the shape of the second high-conduction portion 432, or the like.

The second high-conduction portion 432 can be formed through a method similar to the method of forming the first high-conduction portion 31. For example, the second recess portion 434 for forming the second high-conduction portion 432 can be formed through a method such as wet etching, dry etching, or laser irradiation. The second high-conduction portion 432 may be formed by irradiating the amorphous layer 20 with a laser to crystallize a portion of the amorphous layer 20 without forming the second recess portion 434. The second recess portion 434 may be formed to penetrate through the amorphous layer 20, and an oxide layer may be provided between the substrate 18 or the amorphous layer 20 and the second high-conduction portion 432. Aside from the above, similarly to the method illustrated in FIG. 14, the second-conductivity-type semiconductor layer 22 may be formed on the amorphous layer 20, and the second-conductivity-type semiconductor layer 22 may be irradiated from the above with a laser. Thus, the second high-conduction portion 432 may be provided in the amorphous layer 20, and a crystalline semiconductor portion may be formed on the second high-conduction portion 432.

According to the present modification, the second high-conduction portion 432 is provided in the second region W2. Thus, the resistance in the second region W2 can be reduced. In addition, the amount of the second high-conduction portion 432 in the second region W2 is smaller than the amount of the first high-conduction portion 31 in the first region W1. Thus, a decrease in the passivation property in the second region W2 can be suppressed. The vicinity of the second region W2 has a higher concentration of minority carriers than the vicinity of the first region W1, and a higher passivation property is required in the second region W2 than in the first region W1 in order to prevent carrier recombination at the interface. In addition, the area of the second region W2 is greater than the area of the first region W1. Thus, the current density is lower in the second region W2 than in the first region W1, and even if the series resistance is reduced, its contribution to the power generation efficiency improvement is small. According to the present modification, the amount of the second high-conduction portion 432 is smaller in the second region W2 than in the first region W1. Thus, while suppressing a noticeable decrease in the passivation property, the resistance in the second region W2 can be reduced, and the power generation efficiency of the solar cell 410 can be improved.

The amount of the second high-conduction portion 432 provided per unit are need not be smaller than the amount of the first high-conduction portion 31 provided per unit area. In other words, the amount of the second high-conduction portion 432 provided per unit area may be equivalent to the amount of the first high-conduction portion 31 provided per unit area or may be greater than the amount of the first high-conduction portion 31 provided per unit area.

A solar cell (410) according to an aspect may further include a second high-conduction portion (432) provided inside a second recess portion (434) in the amorphous layer (20) in the second region (W2), the second high-conduction portion (432) having a higher conductivity than the amorphous layer (20), the second high-conduction portion (432) being in contact with the second-conductivity-type semiconductor layer (22).

An amount of the first high-conduction portion 31 provided per unit area in the first region (W1) may be greater than an amount of the second high-conduction portion (432) provided per unit area in the second region (W2).

The second high-conduction portion (432) may include an amorphous semiconductor of the second conductivity type.

The second high-conduction portion (432) may include a crystalline semiconductor.

The second-conductivity-type semiconductor layer (22) may include an amorphous semiconductor of the second conductivity type.

The second-conductivity-type semiconductor layer (22) may include an amorphous semiconductor portion of the second conductivity type provided on the amorphous layer (20) and a crystalline semiconductor portion of the second conductivity type provided on the second high-conduction portion (432).

### (Fifth Modification)

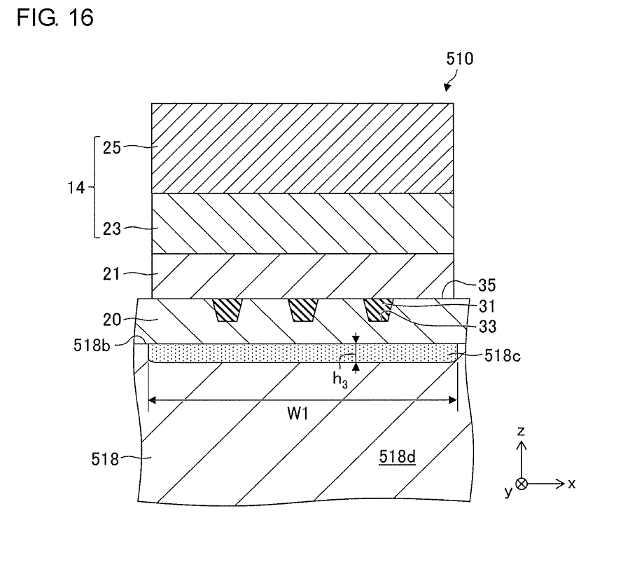

FIG. 16 is a sectional view illustrating a structure of a solar cell 510 according to a modification. The present modification differs from the embodiment described above in that a high-impurity-concentration region 518c having a higher concentration of an impurity of the first conductivity type is provided in a substrate 518 in the first region W1. Therefore, the substrate 518 includes a bulk region 518d having a lower concentration of the impurity of the first conductivity type and the high-impurity-concentration region 518c having a higher concentration of the impurity of the first conductivity type.

The high-impurity-concentration region 518c is provided in the first region W1 to avoid the second region W2. The impurity concentration in the high-impurity-concentration region 518c is approximately 1×10¹⁷/cm³ to 1×10²⁰/cm³ and can be approximately 1×10¹⁸/cm³ to 2×10¹⁹/cm³, for example. The high-impurity-concentration region 518c includes, for example, phosphorus (P) as the impurity of the first conductivity type.

The high-impurity-concentration region 518c is formed to have a depth h₃ from a second principal surface 518b of no more than 5 μm, and the depth h₃ can be approximately 5 nm to 200 nm, for example. The high-impurity-concentration region 518c can be formed, for example, by diffusing the impurity of the first conductivity type from the second principal surface 518b in the first region W1. The high-impurity-concentration region 518c may be formed through an ion implantation process.

In place of providing the high-impurity-concentration region 518c, a high-impurity-concentration layer of the first conductivity type may be provided between the second principal surface 518b of the substrate 518 and the amorphous layer 20 in the first region W1. This high-impurity-concentration layer can be formed, for example, of crystalline silicon, amorphous silicon, silicon oxide, silicon oxynitride, silicon nitride, or the like. The high-impurity-concentration layer is provided to have a thickness of no more than 10 nm and, for example, has a thickness of preferably 0.1 nm to 3 nm and more preferably no more than 2 nm.

According to the present modification, the high-impurity-concentration region 518c or the high-impurity-concentration layer is provided. Thus, the minority carriers in the vicinity of the first region W1 can be further reduced to improve the passivation property. Thus, a decrease in the passivation property resulting from providing the first high-conduction portion 31 in the amorphous layer 20 in the first region W1 can be compensated, and the passivation property and the lower resistance property can both be achieved favorably.

In a solar cell (510) according to an aspect, a high-impurity-concentration region (518c) may be provided at an interface between a substrate (518) and the amorphous layer (20) in the first region (W1), the high-impurity-concentration region (518c) having a higher concentration of an impurity of the first conductivity type than the substrate (518).

### (Sixth Modification)

The embodiment and the modifications described above illustrate cases in which the first-conductivity-type semiconductor layer 21 and the second-conductivity-type semiconductor layer 22 are provided on the amorphous layer 20. In a further modification, a first amorphous layer may be provided on the substrate 18 in the first region W1, and a second amorphous layer different from the first amorphous layer may be provided on the substrate 18 in the second region W2. The first amorphous layer and the second amorphous layer may be formed of the same material (compound) or may be formed of different compounds. In this case, the first-conductivity-type semiconductor layer 21 is provided on the first amorphous layer, and the first high-conduction portion 31 is provided in the first amorphous layer. In addition, the second-conductivity-type semiconductor layer 22 is provided on the second amorphous layer. The second high-conduction portion 432 may be provided in the second amorphous layer.

The first amorphous layer and the second amorphous layer may both be formed of a substantially intrinsic amorphous semiconductor. In this case, the second amorphous layer may have a lower film density than the first amorphous layer. For example, the film density of the first amorphous layer may be no lower than 2.2 g/cm³ nor higher than 2.4 g/cm³, and the film density of the second amorphous layer may be no lower than 2.0 g/cm³ nor higher than 2.2 g/cm³.

At least one of the first amorphous layer and the second amorphous layer may be an amorphous insulator. Furthermore, the first amorphous layer may be formed of an amorphous semiconductor of the first conductivity type, and the second amorphous layer may be formed of an amorphous semiconductor of the second conductivity type. Aside from the above, the first amorphous layer may be an i-type amorphous semiconductor or amorphous insulator, and the second amorphous layer may be of the second conductivity type. Conversely, the first amorphous layer may be of the first conductivity type, and the second amorphous layer may be an i-type amorphous semiconductor or amorphous insulator.

### Second Embodiment

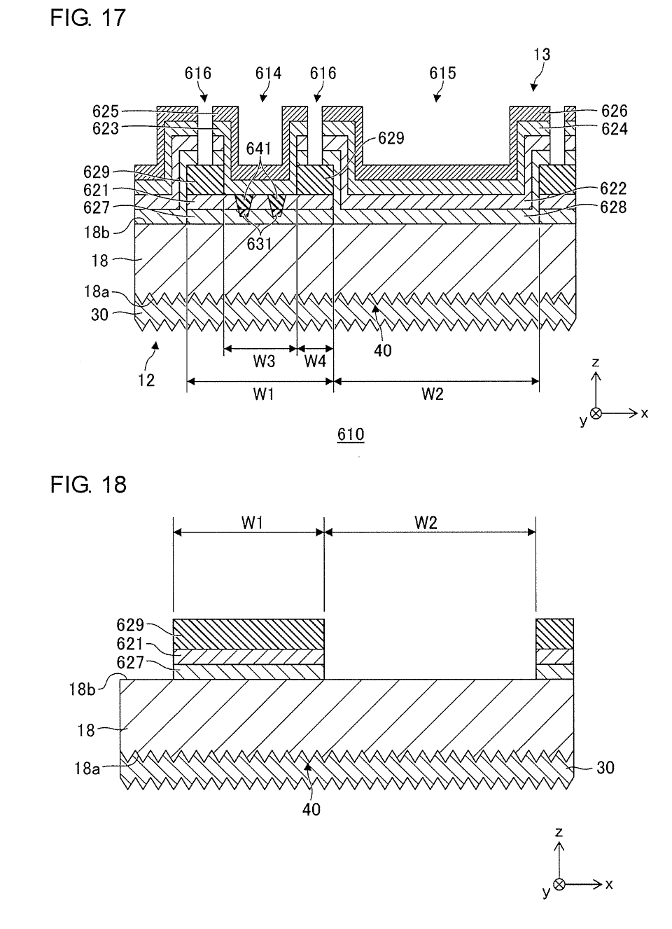

FIG. 17 is a sectional view illustrating a structure of a solar cell 610 according to another embodiment. In the present embodiment, instead of providing a single amorphous layer 20 on the second principal surface 18b of the substrate 18, a first amorphous layer 627 is provided in the first region W1, and a second amorphous layer 628 is provided in the second region W2. In addition, the present embodiment differs from the embodiment described above in that a first-conductivity-type semiconductor layer 621 and a second-conductivity-type semiconductor layer 622 are provided to overlap each other with an insulation layer 629 interposed therebetween in a fourth region W4 that is a portion of the first region W1. The present embodiment will be described with the descriptions centered on the differences from the embodiment described above.

The solar cell 610 includes the substrate 18, the light-receiving surface protection layer 30, the first-conductivity-type semiconductor layer 621, the second-conductivity-type semiconductor layer 622, a first transparent electrode layer 623, a second transparent electrode layer 624, a first metal electrode layer 625, a second metal electrode layer 626, the first amorphous layer 627, the second amorphous layer 628, and the insulation layer 629.

The first amorphous layer 627 is provided on the second principal surface 18b of the substrate 18 in the first region W1. The first amorphous layer 627 is formed of an i-type or n-type amorphous semiconductor or an insulator. When the first amorphous layer 627 is formed of an i-type or n-type amorphous semiconductor, the first amorphous layer 627 can be formed, for example, of i-type or n-type amorphous silicon containing hydrogen. Meanwhile, when the first amorphous layer 627 is formed of an insulator, the first amorphous layer 627 can be formed, for example, of a silicon compound or an aluminum compound containing at least one of oxygen and nitrogen. The first amorphous layer 627 has a thickness of approximately 1 nm to 200 nm and preferably has a thickness of approximately 2 nm to 25 nm. The first-conductivity-type semiconductor layer 621 is provided on the first amorphous layer 627.

The second amorphous layer 628 is provided on the second principal surface 18b of the substrate 18 in the second region W2. The second amorphous layer 628 is formed of an i-type or p-type amorphous semiconductor or an insulator. When the second amorphous layer 628 is formed of an i-type or p-type amorphous semiconductor, the second amorphous layer 628 can be formed, for example, of i-type or p-type amorphous silicon containing hydrogen. Meanwhile, when the second amorphous layer 628 is formed of an insulator, the second amorphous layer 628 can be formed, for example, of a silicon compound or an aluminum compound containing at least one of oxygen and nitrogen. The second amorphous layer 628 has a thickness of approximately 1 nm to 200 nm and preferably has a thickness of approximately 2 nm to 25 nm. The second amorphous layer 628 may be formed to have a lower film density than the first amorphous layer 627. The second-conductivity-type semiconductor layer 622 is provided on the second amorphous layer 628.

The insulation layer 629 is formed of an insulating material and formed, for example, of silicon oxide (SiO), silicon nitride (SiN), silicon oxynitride (SiON), or the like. The insulation layer 629 is provided on the first-conductivity-type semiconductor layer 621. The insulation layer 629 is not provided in a third region W3 corresponding to a middle portion of the first region W1 in the x-direction. The insulation layer 629 is provided in the fourth region W4 that is on each side of the third region W3. The fourth region W4, in which the insulation layer 629 is provided, has a width in the x-direction that is, for example, approximately one-third the width of the first region W1 in the x-direction. In addition, the third region W3, in which the insulation layer 629 is not provided, has a width in the x-direction that is approximately one-third the width of the first region W1.

The second amorphous layer 628 and the second-conductivity-type semiconductor layer 622 are provided to overlie the insulation layer 629 in the fourth region W4. Thus, the second amorphous layer 628 and the second-conductivity-type semiconductor layer 622 overlie the first amorphous layer 627 and the first-conductivity-type semiconductor layer 621 in the lamination direction (z-direction) in the fourth region W4.

The first transparent electrode layer 623 and the first metal electrode layer 625 are provided on the first-conductivity-type semiconductor layer 621. The second transparent electrode layer 624 and the second metal electrode layer 626 are provided on the second-conductivity-type semiconductor layer 622. A first electrode 614 is constituted by the first transparent electrode layer 623 and the first metal electrode layer 625, and a second electrode 615 is constituted by the second transparent electrode layer 624 and the second metal electrode layer 626. An isolation groove 616 is provided between the first electrode 614 and the second electrode 615 to electrically isolate therebetween. The isolation groove 616 is provided on the insulation layer 629 in the fourth region W4.

The solar cell 610 further includes a first high-conduction portion 631 and a crystalline semiconductor portion 641. The first high-conduction portion 631 is provided in the first amorphous layer 627 and provided, in particular, in the first amorphous layer 627 in the third region W3. The crystalline semiconductor portion 641 is provided in the first-conductivity-type semiconductor layer 621 and provided, in particular, on the first high-conduction portion 631 in the third region W3. In the present embodiment as well, the first high-conduction portion 631 and the crystalline semiconductor portion 641 are provided. Thus, the series resistance in the third region W3 that has a smaller area than the second region W2 can be reduced, and the power generation efficiency of the solar cell 610 can be increased.

Next, a method of manufacturing the solar cell 610 will be described. First, as illustrated in FIG. 18, the light-receiving surface protection layer 30 is formed on the first principal surface 18a, and the first amorphous layer 627, the first-conductivity-type semiconductor layer 621, and the insulation layer 629 are formed on the second principal surface 18b in the first region W1. The first amorphous layer 627, the first-conductivity-type semiconductor layer 621, and the insulation layer 629 can be formed selectively in the first region W1 by, for example, forming a mask in the second region W2. Aside from the above, a protection mask may be formed in the first region W1 after the first amorphous layer 627, the first-conductivity-type semiconductor layer 621, and the insulation layer 629 are formed on the entire surface of the second principal surface 18b, and these layers may be removed from the second region W2.

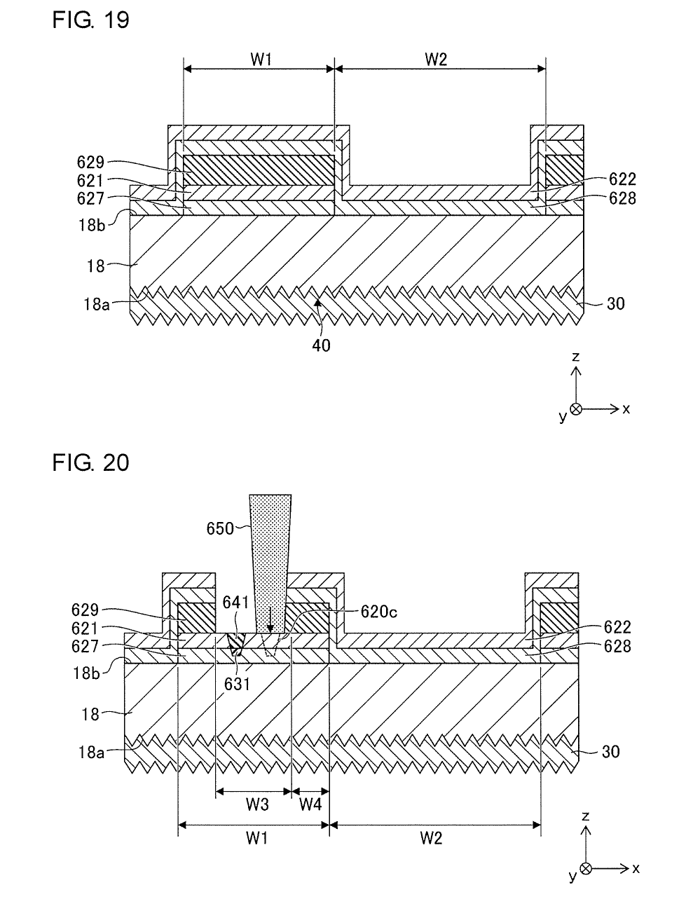

Next, as illustrated in FIG. 19, the second amorphous layer 628 and the second-conductivity-type semiconductor layer 622 are formed in the first region W1 and the second region W2. The second amorphous layer 628 is formed on the insulation layer 629 in the first region W1 and formed on the second principal surface 18b in the second region W2. The second-conductivity-type semiconductor layer 622 is formed on the second amorphous layer 628.

Then, as illustrated in FIG. 20, the third region W3 in the middle portion of the first region W1 is irradiated with a laser 650, and the insulation layer 629, the second-conductivity-type semiconductor layer 622, and the second amorphous layer 628 in the third region W3 are removed. Thus, the first-conductivity-type semiconductor layer 621 is exposed in the third region W3. In addition, a portion of the first-conductivity-type semiconductor layer 621 and a portion of the first amorphous layer 627 are heated by the laser 650, with which the third region W3 is being irradiated, to crystallize an irradiation region 620c. Thus, the crystalline semiconductor portion 641 is formed in a portion of the first-conductivity-type semiconductor layer 621, and the first high-conduction portion 631 is formed in a portion of the first amorphous layer 627.

The first high-conduction portion 631 and the crystalline semiconductor portion 641 can be formed simultaneously when the insulation layer 629 is removed. For example, the insulation layer 629 may be removed upon being irradiated with the laser 650, and this irradiation with the laser 650 may also form the first high-conduction portion 631 and the crystalline semiconductor portion 641 immediately underneath the removed insulation layer 629. In other words, the insulation layer 629 provided on the first-conductivity-type semiconductor layer 621 and the first amorphous layer 627 may be irradiated from the above with the laser 650, and thus the first high-conduction portion 631 and the crystalline semiconductor portion 641 may be formed.

The first high-conduction portion 631 and the crystalline semiconductor portion 641 may be formed in an instance separate from the removal of the insulation layer 629. For example, the first-conductivity-type semiconductor layer 621 and the first amorphous layer 627 may be irradiated with the laser 650 after the insulation layer 629 is removed. Thus, the process of removing the insulation layer 629 and the process of forming the first high-conduction portion 631 and the crystalline semiconductor portion 641 may be carried out separately. In this case, the insulation layer 629, the second amorphous layer 628, and the second-conductivity-type semiconductor layer 622 in the third region W3 may each be removed through laser irradiation, through dry etching or wet etching, or through a combination of these techniques. For example, the second-conductivity-type semiconductor layer 622 and the second amorphous layer 628 may be partially removed through laser irradiation. Then, the exposed insulation layer 629 may be removed through wet etching.

Next, a transparent electrode layer is provided on the first-conductivity-type semiconductor layer 621 exposed in the third region W3 and the second-conductivity-type semiconductor layer 622 exposed in the second region W2 and the fourth region W4, and a metal electrode layer is provided on the transparent electrode layer. Thereafter, the isolation groove 616 is formed in the fourth region W4, and the first electrode 614 and the second electrode 615 are thus formed. Thus, the solar cell 610 illustrated in FIG. 17 is fabricated.

An aspect of the present embodiment is as follows. A solar cell (610) according to an aspect includes:

a crystalline semiconductor substrate (18) of a first conductivity type or a second conductivity type;

a first amorphous layer (627) provided on a principal surface (second principal surface 18b) of the substrate (18);

a first-conductivity-type semiconductor layer (621) provided on the first amorphous layer (627);

a first high-conduction portion (631) provided inside a first recess portion in the first amorphous layer (627), the first high-conduction portion (631) having a higher conductivity than the first amorphous layer (627), the first high-conduction portion (631) being in contact with the first-conductivity-type semiconductor layer (621); and

a first electrode (614) provided on the first-conductivity-type semiconductor layer (621).

The first amorphous layer (627) and the first-conductivity-type semiconductor layer (621) may be provided on the principal surface (second principal surface 18b) of the substrate (18) in a first region (W1), and the solar cell (610) may further include

a second amorphous layer (628) provided on the principal surface (second principal surface 18b) of the substrate (18) in a second region (W2) different from the first region (W1),

a second-conductivity-type semiconductor layer (622) provided on the second amorphous layer (628), and

a second electrode (615) provided on the second-conductivity-type semiconductor layer (622).

The substrate (18) may be of the first conductivity type, and an area of the first region (W1) may be smaller than an area of the second region (W2).

Another aspect of the present embodiment provides a method of manufacturing a solar cell (610). This method includes:

forming a first amorphous layer (627) on a principal surface (second principal surface 18b) of a substrate (18) in a first region (W1);

forming a first high-conduction portion (631) in the first amorphous layer (627), the first high-conduction portion (631) having a higher conductivity than the first amorphous layer (627);

forming a first-conductivity-type semiconductor layer (621) on the first amorphous layer (627);

forming a second amorphous layer (628) on the principal surface (second principal surface 18b) in a second region (W2) different from the first region (W1);

forming a second-conductivity-type semiconductor layer (622) on the second amorphous layer (628); and

forming a first electrode (614) on the first-conductivity-type semiconductor layer (621) and a second electrode (615) on the second-conductivity-type semiconductor layer (622).

The first high-conduction portion (631) maybe formed by irradiating, from the above, an insulation layer (629) formed on the first amorphous layer (627) with a laser.

Thus far, the present invention has been described with reference to the foregoing embodiments. The present invention, however, is not limited to the foregoing embodiments and also encompasses an embodiment obtained by combining or replacing configurations of the foregoing embodiments and modifications as appropriate.

It should be understood that the invention is not limited to the above-described embodiment, but may be modified into various forms on the basis of the spirit of the invention. Additionally, the modifications are included in the scope of the invention.

What is claimed is:

1. A solar cell, comprising:
a crystalline semiconductor substrate of a first conductivity type or a second conductivity type;
a first amorphous layer provided on a principal surface of the substrate;
a first-conductivity-type semiconductor layer provided on the first amorphous layer;
a first high-conduction portion provided inside a first recess portion in the first amorphous layer, the first high-conduction portion having a higher conductivity than the first amorphous layer, the first high-conduction portion being in contact with the first-conductivity-type semiconductor layer; and
a first electrode provided on the first-conductivity-type semiconductor layer.

2. The solar cell according to claim 1, wherein
the first amorphous layer and the first-conductivity-type semiconductor layer are provided on the principal surface of the substrate in a first region,
the solar cell further comprising:
a second amorphous layer provided on the principal surface of the substrate in a second region different from the first region;
a second-conductivity-type semiconductor layer provided on the second amorphous layer; and
a second electrode provided on the second-conductivity-type semiconductor layer.

3. The solar cell according to claim 2, wherein
the substrate is of the first conductivity type, and
an area of the first region is smaller than an area of the second region.

4. The solar cell according to claim 2, wherein
the first amorphous layer and the second amorphous layer are constituted by a shared amorphous layer.

5. The solar cell according to claim 1, wherein
the first high-conduction portion includes an amorphous semiconductor of the first conductivity type.

6. The solar cell according to claim 1, wherein
the first high-conduction portion includes a crystalline semiconductor.

7. The solar cell according to claim 1, wherein
the first high-conduction portion and the first-conductivity-type semiconductor layer are formed of the same material.

8. The solar cell according to claim 1, wherein
the first recess portion has a depth that is no less than 5% nor more than 95% of a height from the principal surface of the substrate to an interface between the first amorphous layer and the first-conductivity-type semiconductor layer.

9. The solar cell according to claim 1, wherein
the first recess portion penetrates through the first amorphous layer to reach the substrate.

10. The solar cell according to claim 9, wherein
an oxide layer is provided at an interface between the substrate and the first high-conduction portion.

11. The solar cell according to claim 1, wherein
an oxide layer is provided at an interface between the first amorphous layer and the first high-conduction portion.

12. The solar cell according to claim 1, wherein
the first recess portion has a section along a plane orthogonal to a depthwise direction, and a size of the section decreases as a distance from an interface between the first amorphous layer and the first-conductivity-type semiconductor layer increases.

13. The solar cell according to claim 1, wherein
a fine recess portion is provided in the principal surface of the substrate at a position corresponding to the first high-conduction portion.

14. The solar cell according to claim 1, wherein
the first-conductivity-type semiconductor layer includes a crystalline semiconductor portion and an amorphous semiconductor portion, and
the crystalline semiconductor portion is provided on the first high-conduction portion.

15. A method of manufacturing a solar cell, the method comprising:
forming an amorphous layer on a principal surface of a crystalline semiconductor substrate of a first conductivity type;
forming a first high-conduction portion in the amorphous layer in a first region, the first high-conduction portion having a higher conductivity than the amorphous layer;
forming a first-conductivity-type semiconductor layer on the amorphous layer in the first region;
forming a second-conductivity-type semiconductor layer on the amorphous layer in a second region different from the first region; and
forming a first electrode on the first-conductivity-type semiconductor layer and a second electrode on the second-conductivity-type semiconductor layer.
